(19) United States
(12) Patent Application Publication
(10) Pub. No.: US 2007/0215987 A1
(43) Pub. Date: Sep. 20, 2007

(54) METHOD FOR FORMING A MEMORY DEVICE AND MEMORY DEVICE

(76) Inventor: Ulrike Gruening-von Schwerin, Munich (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/376,445

(22) Filed: Mar. 15, 2006

(51) Int. Cl. H01L 23/58; H01L 21/461

(52) U.S. Cl. 257/635; 438/692; 438/763; 257/640

(57) ABSTRACT

A phase change memory device and method of forming a phase change memory device is disclosed. The method includes forming a memory device with a plurality of memory cells, each memory cell having a pillar containing a region of an active material, said method comprising the steps of: depositing at least a thermally insulating base layer on a surface that comprises said pillars; depositing a top layer on top of said base layer, said base layer having a higher resistance against polishing than said top layer; and planarizing a top surface by polishing such that at least the parts of said base layer above said pillars are exposed. The invention further relates to a memory device fabricated by this method.

### FIELD OF THE INVENTION

The invention relates to a memory device with a plurality of memory cells, in particular PCM memory cells, and to a method for forming/producing such a memory device.

### BACKGROUND

In the case of conventional memory devices, in particular conventional semiconductor memory devices, one differentiates between so-called functional memory devices (e.g. PLAs, PALS, etc.), and so-called table memory devices, e.g. ROM devices (ROM=Read Only Memory−in particular PROMs, EPROMs, EEPROMs, flash memories, etc.), and RAM devices (RAM=Ran [symbol] dom Access Memory or read-write memory, e.g. DRAMs and SRAMs).

A RAM device is a memory for storing data under a predetermined address and for reading out the data under this address later.

In the case of SRAMs (SRAM=Static Random Access Memory), the individual memory cells consist e.g. of few, for instance 6, transistors, and in the case of so-called DRAMs (DRAM=Dynamic Random Access Memory) in general only of one single, correspond [symbol] ingly controlled capacitive element (e.g. the gate-source capacitor of a MOSFET) with the capacitance of which one bit each can be stored as charge.

This charge, however, remains for a short time only. Therefore, a so-called “refresh” must be performed regularly, e.g. approximately every 64 ms.

In contrast to that, no “refresh” has to be performed in the case of SRAMs, i.e. the data stored in the memory cell remain stored as long as an appropriate supply voltage is fed to the SRAM.

In the case of non-volatile memory devices (NVMs), e.g. EPROMs, EEPROMs, and flash memories, the stored data remain, however, stored even when the supply voltage is switched off.

Furthermore, so-called “resistive” or “resistively switching” memory devices have also become known recently, e.g., so-called Phase Change Memories (“PCMs”).

In the case of “resistive” or “resistively switching” memory devices, an “active” or “switching active” material—which is, for instance, positioned between two appropriate electrodes (i.e. an anode and a cathode)—is placed, by appropriate switching processes, in a more or less conductive state (wherein e.g. the more conductive state corresponds to a stored, logic “One”, and the less conductive state to a stored, logic “Zero”, or vice versa). This may, for instance, correspond to the logic arrangement of a bit.

In the case of phase change memories (PCRAMs), for instance, an appropriate chalcogenide compound may be used as a “switching active” material that is positioned between two corresponding elec [symbol] trodes (e.g. a Ge—Sb—Te (“GST”) or an Ag—In—Sb—Te com [symbol] pound). The chalcogenide compound material is adapted to be placed in an amorphous, i.e. a relatively weakly conductive, or a crystalline, i.e. a relatively strongly conductive state by appropriate switching processes (wherein e.g. the relatively strongly conductive state may correspond to a stored, logic “1”, and the relatively weakly conductive state may correspond to a stored, logic “0”, or vice versa).

Phase change memory cells are, for instance, known from G. Wicker, “Nonvolatile, High Density, High Performance Phase Change Memory”, SPIE Conference on Electronics and Structures for MEMS, Vol. 3891, Queensland, 2, 1999, and e.g. from Y. N. Hwang et al., “Completely CMOS Compatible Phase Change Nonvolatile RAM Using NMOS Cell Transistors”, IEEE Proceedings of the Nonvolatile Semiconductor Memory Workshop, Monterey, 91, 2003, S. Lai et al., “OUM-a 180 nm nonvolatile memory cell element technology for stand alone and embedded applications”, IEDM 2001, etc.

In order to achieve, with a corresponding memory cell, a change from an amorphous, i.e. a relatively weakly conductive state of the switching active material, to a crystalline, i.e. a relatively strongly conductive state, an appropriate heating current pulse can be applied at the electrodes, said heating current pulse resulting in that the switching active material is heated beyond the crystallization temperature and crystallizes (“writing process” or “setting”).

Vice versa, a change of state of the switching active material from a crystalline, i.e. a relatively strongly conductive state, to an amorphous, i.e. a relatively weakly conductive state, may, for instance, be achieved in that—again by means of an appropriate heating current pulse—the switching active material is heated beyond the melting temperature and is subsequently “quenched” to an amorphous state by quick cooling (“deleting process” or “resetting”).

Phase change memory cells based on this or a corresponding principle are, for instance, described in the publication Y. Ha et al.: “An edge contact type cell for phase change RAM featuring very low power consumption”, VLSI 2003, and e.g. in H. Horii et al.: “A novel cell technology using N-doped GeSbTe films for phase change RAM”, VLSI 2003, Y. Hwang et al.: “Full integration and reliability evaluation of phase-change RAM based on 0.24 μm-CMOS technologies”, VLSI 2003, and S. Ahn et al.: “Highly Manufacturable High Density Phase Change Memory of 64 Mb and beyond”, IEDM 2004, etc.

In order that a corresponding memory device can function reliably, the above-mentioned delete or write heating current pulses to be applied to the respective memory cells each have to have heights that have correspondingly been predefined relatively exactly.

The transistors driving the delete or write heating current pulses—e.g. via appropriate bit and ground lines—therefore have to be dimensioned with relatively high accuracy.

The magnitude of the current required to reliably set or reset a cell depends an the size of the heating element. It is hence desirable to use small sublithographic feature sizes for the memory cell and active element.

One example for a fabrication of the memory cell is the so-called ‘pillar cell’ where the memory cell is formed by etching of memory element layers resulting in oblong stacks (‘pillars’) with a longitudinal axis of these pillars being perpendicular to the underlying substrate. The pillars contain the respective active material/active areas and often a respective top electrode.

However, to continue processing, and e.g. to electrically connect the top electrode contacts of the pillars, the pillars have to be surrounded with filling material which should provide good thermal insulation (e.g., an oxide material) and then have to be planarized on their top surface, which is typically done by CMP (Chemical Mechanical Polishing).

One drawback is that currently the CMP has to use the top electrode as a stopping layer. Underpolishing would result in contact opens, while overpolishing removes part of or the entire top electrode which also results in an insufficient contact. A further current drawback is the small size of the top electrode layer which degrades the potential resistivity of the stopping layer, i.e., the top electrode layer, against erosion. Also, a thick top electrode has to be deposited to provide margin for overpolishing which in turn may lead to adhesion problems due to stress effects.

For these and other reasons, there is a need for the present invention.

### SUMMARY

The present invention provides a phase change memory device and a method of forming a phase change memory device. In one embodiment, the invention relates to method for forming a memory device with a plurality of memory cells, each memory cell having a pillar containing a region of an active material. The method includes depositing at least a thermally insulating base layer on a surface that includes the pillars. A top layer is deposited on top of the base layer, the base layer having a higher resistance against polishing than the top layer. A top surface is planarized by polishing such that at least the parts of the base layer above the pillars are exposed. The invention further relates to a memory device fabricated by this method.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A and 1B illustrate cross-sectional representations of an exemplary structure of a resistively switching memory cell at different processing stages, according to prior art.

FIG. 2 illustrates a top view of the structure of FIG. 1B, according to prior art.

FIG. 3A to 3C illustrate cross-sectional representations similar to FIGS. 1A and 1B of an exemplary structure of a resistively switching memory cell at different processing stages, according to one embodiment of the invention.

FIG. 4 illustrates a top view of the structure of FIG. 3C, according to one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a novel memory device with a plurality of memory cells, in particular PCM memory cells, and a novel method for forming such a memory device, in particular a method and a memory device.

In accordance with one embodiment of the invention there is provided a method for forming a memory device with a plurality of memory cells which comprises depositing at least a base layer on the surface that comprises the pillars, the base layer at least having a thermal, and preferably an electrically, insulating property, and depositing a top layer on top of the base layer. The base layer has a stronger polishing (esp. CMP polishing) stopping property than the top layer, i.e., shows a greater resistance against polishing. Thus can be achieved both a sufficient thermal and, preferably, electrically, insulation for the memory cell as well as a designated, improved stopping capability for the CMP process to follow formation of the memory cell.

The top electrode is protected during a following planarization process and is advantageously opened in a well-defined selective etch after planarization. This allows a reduction of the top electrode thickness which is beneficial for stress and pillar height.

It is especially preferred if the base layer is comprised of at least two consecutive (sub)layers, i.e. a first layer to be deposited on the surface that comprises the pillars and a second layer to be deposited on top of the first layer. The top layer is than a third layer. By using several (base) layers one can better set up the properties of the layers since it is more difficult to find one base layer material that serves all necessary conditions. Accordingly, the first layer may be used to both increase the pillar width as well as serve as thermal, and preferably electrical, isolation layer. The second layer is mostly used as a CMP stop and its thickness is accordingly chosen to be sufficiently thick to act as CMP stop layer. Consequently, the CMP resistance of the second layer should be greater that that of the top/third layer while its insulating properties may be negligible. Vice versa, the CMP stopping property of the first layer may be negligible.

In one embodiment, a top (e.g., third) third layer is deposited to fill the remaining topography and may then be planarized, e.g. with a CMP stop on the second layer.

Due to the arrangement of the pillar PCRAM cells in an array, the thickness of the first two layers can be chosen such that the nearest distance between neighboring cells is filled, hence considerably increasing the pad area.

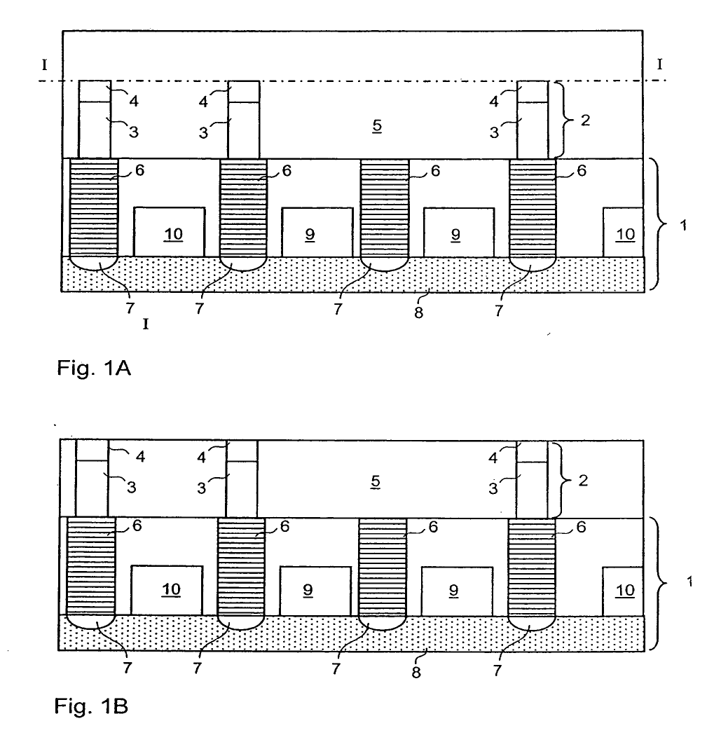

FIG. 1A illustrates a cross-sectional cut-out of a resistively switching memory device at a first processing/production stage. At this stage, on top of a substrate 1 there are formed pillars 2 that comprise an active phase change material 3 and on top of that an electrode material 4. The pillars 2 are covered top and sides by an insulation layer 5 to insulate the pillars 2 thermally and electrically. At its bottom the active phase change material 3 is connected to the substrate 1, more precisely: to a contact-to-array 6 to one side of the source-drain path 6 of a transistor. Generally, the substrate is multi-functional and comprises several components of which are shown: a gate conductor electrode 9 of an transistor; an active area 8 of the substrate 1; a source/drain area 7 in the substrate that is connected to the active phase change material 3 via the contact-to-array 6; and insulating gates 10 which in one embodiment are always turned off and electrically isolate two neighboring memory elements. The functions and co-operation of these and further components of the substrate are known to those skilled in the art.

The memory device of this production stage must be processed further in order to, inter alia, add other functional elements like Bit Lines etc. on top of the electrode material 4. To do so, the insulation layer 5 is removed downwards to a level—as indicated by the line I-I—that opens the electrode material 4 for further electrical contacting and planarizes the top surface on that level (see FIG. 1B). That is often done by CMP (Chemical Mechanical Polishing).

FIG. 1B illustrates a cross-sectional cut-out of a resistively switching memory cell at a second processing/production stage which corresponds to a condition after CMP polishing of the memory cell of FIG. 1A. Here further elements like planar layers etc can be added.

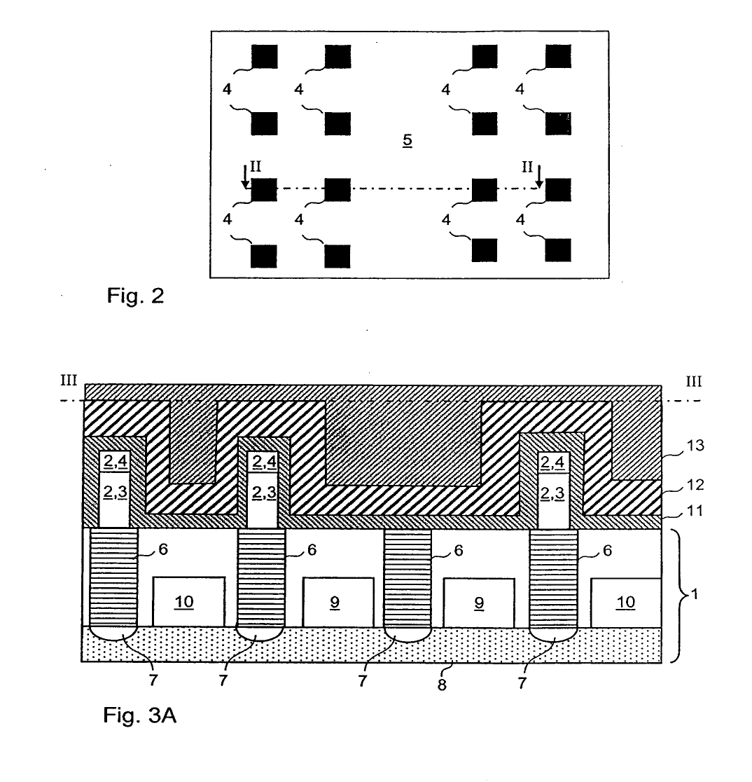

FIG. 2 illustrates a top view onto the polished top surface of the resistively switching memory cell of FIG. 1B with electrode material 4 areas within the insulation layer 5. The cut-out of FIGS. 1A and 1B is shown by the line II-II which limits are depicted by the arrows.

If a CMP polish is performed down to the surface level I-I starting from a higher surface level where only the insulation layer 5 is present (see FIG. 1A), it should be sufficient selectivity in the polishing process between material 5 and 4 to effectively stop the planarizing process at the top of 4 without removing too much of it.

Starting from the condition of FIG. 1A, the ability to stop the CMP polishing o(or what is meant to be included: to alter, e.g. increase, the resistance of the surface to the polishing process such that the change of the composition/configuration of the surface can be detected and subsequently the polishing process can be stopped) depends, inter alia, on the surface area of the electrode material and its different resistance to polishing vis-a-vis the insulating layer 5, respectively.

In the shown conventional arrangement the surface area of the electrode material 4 areas is much smaller than the area of the insulation layer 5 such that the CMP process cannot be performed with the required precision. This may result in overpolishing. If the polishing process is stopped after a predetermined time or depth, over- or underpolishing can occur.

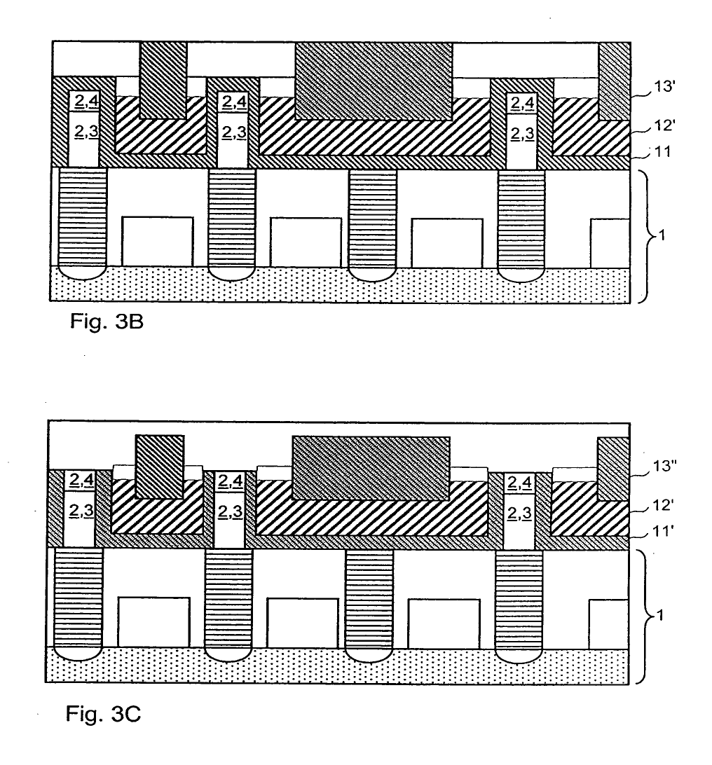

FIG. 3A illustrates a cross-sectional cut-out of a preferred embodiment of a resistively switching memory device according to the invention at a first processing/production stage.

Here, the substrate 1 and the pillars 2 are the same as in FIGS. 1A and 1B but now the pillars 2 are covered by three consecutive layers 11, 12, 13. A first layer 11 has been deposited on a surface that comprises the substrate 1 and the pillars 2.

The first layer 11 is at least thermally insulating (having a thermal conductivity of preferably less than 1.3 W/K m) and covers the substrate 1 as well as the pillars 2; the pillars 2 now being fully covered at their formerly exposed areas, i.e. on top and on the sides. The first layer 11 may contain every suitable at least thermally—and preferably electrically—insulating material such as e.g. a suitable dielectric material, oxide material, and so on, like e.g. (e.g. porous) SiO2, FSG, BPSG, BSG, aerogels, xerogels, further low-k material etc., alone or in combination, of which an oxide material is preferred.

The thickness of the first layer 11 is smaller than the space of the pillars 2 in at least one direction such that after deposition of the first, insulating layer 11 open space remains at least between one direction of the pillars 2.

The second layer 12 has the ability to act as a stopping layer for CMP polishing, i.e., the CMP polish rate is remarkably lower than for the material (see below) which should be planarized later.

Thus the first layer 11 and the second layer 12 can be regarded as two sublayers that in combination constitute a thermally and electrically insulating base layer.

The thickness of the first layer 11 and the second layer 12 together (i.e. a base layer) is smaller than the lateral space/distance of the pillars 2 such that after deposition of the layers 11, 12 open space still remains between the pillars 2. The second layer may contain SiN.

The third layer 13 covers the second layer 12 and is, inter alia, used to fill up the remaining space between the pillars 2. The third layer 13 may be of the same material as the first layer 11, e.g., an oxide.

Thus, in this preferred embodiment, the third layer 13 is easier to polish than the second layer 12 that exhibits a greater resistance to polishing.

The thickness of the base layer, i.e. the combined first and second layers 11,12, is in this example in the range of 100 nm or more. Preferably, the thickness of each of the combined first and second layers 11,12 is in the range of 100 nm or more.

After having deposited the third layer 13 it will be polished, i.e. planarized, e.g. by CMP polishing, down to the second layer 12, as indicated by line III-III. Because the second layer 12 exhibits a relatively strong resistance against polishing (SiN being a relatively hard material), polishing will then be terminated. The top surface now contains areas of the second layer 12 and areas of the third layer 13 that were filled into the space between the second layer 12 (not shown). If desired for improved topography, the layer 13 can be recessed by a wet or dry etch to the level of the top of electrode 4 (not shown in drawings).

To be able to open the top contacts 4, the second layer 12 is etched instead of being polished with overetching being allowed.

FIG. 3B illustrates the state of the memory cell after the second layer 12 has been etched by an etch that is selective to the material of the second layer 12 but not to the material of the first layer 11 (and in this embodiment also does not etch the third layer 13 that is of the same oxide material as the first layer 11). The etch completely removes the second layer 12 from the first layer 11 on top of the pillars 2 but not from the space between the pillars 2. This fig. also illustrates a slight overetch, i.e. the top surface of the second layer 12 is lower than the top of the pillars 2.

FIG. 3C illustrates the state of the memory device after the first layer 12′ has been etched by an etch that is selective to the material of the first layer 11′ but not to the material of the second layer 12′ (and in this embodiment also does etch the planarized third layer 13″ that is of the same oxide material as the first layer 11′). This second etching step removes the first layer 11′ from the contacts 4 that are now open. This allows a reduction of the top electrode thickness which is beneficial for stress and pillar height.

At this point, the memory device/cell can be equipped with further elements like Bit Lines that have to be contacted with the pillars.

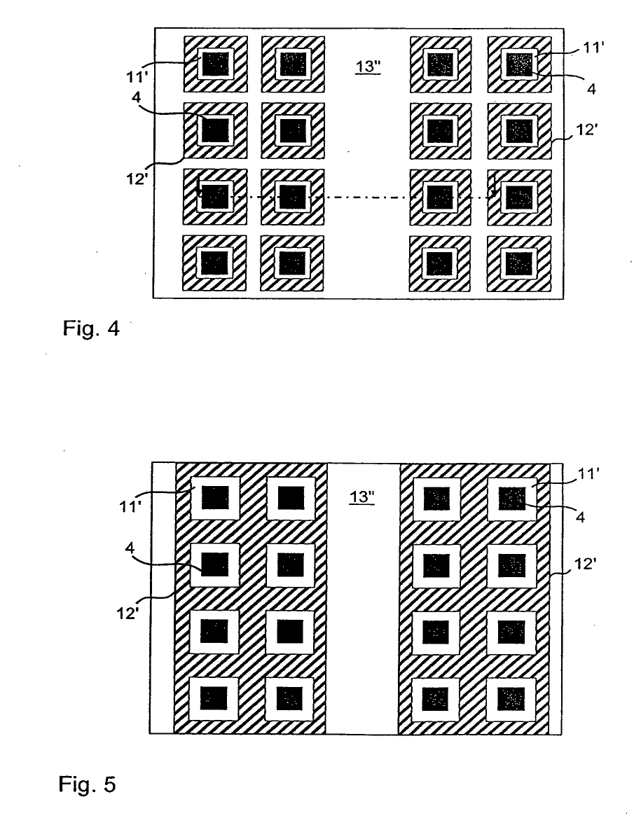

FIG. 4 illustrates a top view of a cut-out of a first memory cell of FIG. 3C. The view of FIG. 3C is sketched by the broken line and the arrows. It illustrates —in this 6 F2 configuration—the contacts 4 that are surrounded by the material of the first layer 11′ and further by the material of the second layer 12′. In between the areas of the second layer 12′ is the material of the planarized and etched third layer 13″.

Since the surface area of the second layer 12, 12′ influences the resistance against polishing, by setting up the thickness of the second layer 12 one can optimize the CMP process window while taking other constraints like gap fill capability and mask removal tolerance into account.

Assuming a 6 F2 cell size, as illustrated in FIG. 4, (F being the minimum feature size) if a pillar is reduced to 0.5 F (more generally 0.3 F to 1 F) in diameter, this may result in an area of about 0.2 F2 (e.g. 0.25 F2 in case of a rectangular pillar or about 0.196 F2 in case of a cylindrical pillar) with respect to 6 F2, which in turn results in a pattern density of less than 4% (0.2 F2/6 F2). In the shown layout, a minimum spacing of the pillars is typically 2 F. If for filling capabilities it is desired that there are no gaps to be filled which are much smaller than 1 F then thickness of the base layer (combined first and second layers) should either be chosen between 0.1 and 0.3 F (minimum space to be filled is then 1.3 F and 0.9 F, resp., for 0.5 F pillars with a 2 F distance/pitch), which results in a pattern density of about 6% and 16%, respectively.

FIG. 5 illustrates a top view similar to FIG. 4 where—in an alternative embodiment—the second layer 12′ has been thicker than in the embodiment of FIG. 4 resulting in a larger surface area of the etched second layer 12′. Accordingly, also a larger surface area of the etched second layer 12′ remains because of the larger thickness. The thickness of the etched second layer 12′ may be so large that gaps between neighboring pillars 2 are completely filled.

In this case—where the nearest neighbor distance is completely filled with the base layer (i.e. the first and second sublayers),—the space to be filled is 2 F or 1 F, a thickness of the base layer is preferably chosen between 0.75 F and 1.25 F, resp., which results in pattern density of 52% or 83%.

Dependent on exact cell layout and basic layout rules, a thickness of the base layer should vary between 0.1 F and 0.2 F or 100 nm, whatever is larger. Preferably, the thickness of each layer should not be significantly smaller than 100 nm.

Generally, by using appropriate combinations of the first and second layer 11,12, esp. regarding material conditions and respective layer thicknesses, one can adjust the stopping characteristics and adapt them for various polishing environments or methods. In extreme cases, layer 11 and 12 may be combined, if thermal, electrical and CMP process related requirements can be fulfilled concurrently.

Although the invention has been described by what is currently regarded as the preferred embodiment, various adaptations and modifications can be made within the scope of the invention.

For example, more than two or three layers can be used, e.g. the first thermally insulating layer can be preceded by a thin electrically insulating layer.

Generally, chalcogenide alloys that contain one or more elements from group VI of the periodic table are useful as such materials. In one embodiment, the phase-change material of phase-change element 106 is made up of a chalcogenide compound material, such as GeSbTe, SbTe, GeTe or AgInSbTe. In another embodiment, the phase-change material is chalcogen free, using active materials such as GeSb, GaSb, InSb, or GeGaInSb. In other embodiments, the phase-change material may be made up of any suitable material including one or more of the elements Ge, Sb, Te, Ga, As, In, Se, and S.

Regarding the second layer 12, instead of SiN one may use e.g. Al2O3, and such.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method for forming a memory device with a plurality of memory cells, each memory cell having a pillar containing a region of an active material, the method comprising:
depositing at least a thermally insulating base layer on a surface that comprises the pillars;
depositing a top layer on top of the base layer, the base layer having a higher resistance against polishing than the top layer; and
planarizing a top surface by polishing such that at least the parts of the base layer above the pillars are exposed.

2. The method according to claim 1, comprising wherein depositing a top layer comprises depositing said top layer on top of said base layer for continuously filling up space between said pillars.

3. The method according to claim 1, further comprising removing said base layer at least above said pillars.

4. The method according to claim 3, comprising wherein removing the base layer is performed by etching.

5. The method according to claim 3, further comprising contacting the pillars.

6. The method according to claim 1, comprising wherein the base layer is also electrically insulating.

7. The method according to claim 1, wherein the active material is a resistively switching material.

8. The method according to claim 7, comprising wherein the active material is a phase change material.

9. The method according to claim 1, comprising wherein the polishing process is a chemical mechanical polishing process.

10. The method according to claim 1, comprising wherein the top layer contains an oxide material.

11. The method according to claim 1, wherein the pillars are formed on top of a planar substrate.

12. The method according to claim 11, wherein the substrate is a multifunctional substrate.

13. The method according to claim 1, wherein the pillars each comprise an electrode above the active material.

14. A method for forming a memory device with a plurality of memory cells, each memory cell having a pillar containing a region of an active material, the method comprising:
depositing at least a thermally insulating base layer on a surface that comprises the pillars;
depositing a top layer on top of the base layer, the base layer having a higher resistance against polishing than the top layer; and
planarizing a top surface by polishing such that at least the parts of the base layer above the pillars are exposed comprising wherein depositing at least the thermally insulating base layer comprises:
depositing a thermally insulating first layer on said surface that comprises said pillars;
depositing a second layer on top of said first layer;
wherein said second layer has a higher resistance against polishing than said top layer.

15. The method according to claim 14, comprising wherein planarizing comprises:
planarizing a top surface by polishing such that at least the parts of said second layer above said pillars are exposed.

16. The method according to claim 15, further comprising:
removing said second layer at least above said pillars.

17. The method according to claim 16, comprising wherein removing said second layer is performed by etching.

18. The method according to claim 16, further comprising:
removing said first layer at least above said pillars.

19. The method according to claim 18, comprising wherein removing the first layer is performed by etching.

20. The method according to claim 14, comprising wherein the second layer is electrically insulating.

21. The method according to claim 14, comprising wherein the first layer comprises an oxide material.

22. The method according to claim 14, comprising wherein the second layer comprises SiN.

23. A memory device with a plurality of memory cells, each memory cell having a pillar containing a region of an active material, said memory device comprising:
a thermally insulating first material laterally surrounding at least said active material of said pillars; and
a second material at least partly laterally surrounding said first material.

24. The memory device according to claim 23, wherein said second material is at least partly laterally surrounded by a further material, said second material having a higher resistance against polishing than said further material.

25. The memory device according to claim 23, comprising wherein said first material comprises an oxide material.

26. The memory device according to claim 23, comprising wherein said second material comprises SiN.

27. The memory device according to claim 24, comprising wherein said further material comprises an oxide material.

28. The memory device according to claim 23, comprising wherein said pillars comprise an electrode material on top of said active material.

29. The memory device according to claim 23, comprising wherein an area ratio within a plane perpendicular to said pillars of said first and second materials to a total area is lager than 5%.

30. The memory device according to claim 29, comprising wherein the area ratio is larger than 15%.

31. The memory device according to claim 30, comprising wherein the area ratio is equal or larger than 50%.

32. The memory device according to claim 31, comprising wherein the area ratio is between 50% and 85%.

33. The memory device according to claim 23, comprising wherein a lateral thickness of said first and second materials is between 0.1 F and 0.3 F.

34. The memory device according to claim 23, comprising wherein a lateral thickness of said first and second materials is between 0.75 F and 1.25 F.

35. The memory device according to claim 23, comprising wherein a lateral thickness of said first material and said second material together is at least 100 nm.

36. The memory device according to claim 35, comprising wherein a lateral thickness of each of said first material and said second material is at least 100 nm.

37. The memory device according to claim 23, comprising wherein said first material is electrically insulating.

38. A memory device with a plurality of memory cells, each memory cell having a pillar containing a region of an active material, said memory device comprising:
means for thermally insulating first material laterally surrounding at least said active material of said pillars; and
a second material at least partly laterally surrounding said means for thermally insulating.

39. The memory device according to claim 38, wherein said second material is at least partly laterally surrounded by a further material, said second material having a higher resistance against polishing than said further material.

40. A method of forming an integrated circuit having a memory device having a plurality of memory cells, each memory cell including a region of active material on a substrate and a pillar of electrode material on top of the resistivity changing material, the method comprising:
depositing a first layer of at least a thermal insulating material to cover the substrate, the active material, and the pillars;
depositing a second layer of at least a thermal insulating material over the first layer, the second layer having a greater polishing resistance than the first layer;
depositing a third layer over the second layer so as to fill any spaces between pillars of adjacent memory cells, the third layer having a lesser polishing resistance than the second layer; and
planarizing a top surface of the memory device by polishing to remove portions of the third layer and expose at least those portions of the second layer above the pillars.

41. The method of claim 40, wherein the first and second layers together form a base layer for thermally and electrically insulating the pillars and active material.

42. The method of claim 40, including selectively etching the second layer so as to remove at least those portions of the second layer from the first layer over the pillars.

43. The method of claim 42, wherein selectively etching includes portions of the second layer such that an upper surface of the second layer is below upper surfaces of the pillars.

44. The method of claim 43, including selectively etching the first layer so as to remove at least those portions of the first layer above the pillars and expose the upper surfaces of the pillars to enable contact of other memory device elements with the pillars.

45. The method of claim 40, wherein the polishing comprises a chemical mechanical polishing process.

46. The method of claim 40, wherein the active material comprises a phase changing material.

47. The method of claim 40, wherein the active material comprises a resistivity changing material.

48. The method of claim 40, wherein the substrate comprises a multifunctional substrate.
